(19) United States
(12) Patent Application Publication
(10) Pub. No.: US 2026/0050022 A1
(43) Pub. Date: Feb. 19, 2026

(54) SENSOR RECEIVER HAVING A SWEEPING PROBE LASER BEAM GENERATED WITHIN A RYDBERG CELL AND ASSOCIATED METHODS

(71) Applicant: Eagle Technology, LLC, Melbourne, FL (US)

(72) Inventors: Victor G. BUCKLEW, Richmond, VA (US); Samuel H. KNARR, Melbourne, FL (US); James A. DRAKES, Occoquan, VA (US); George KANNELL, Florham Park, NJ (US); Dennis ESTRADA, Palm Bay, FL (US); Charles R. TOWERY, Melbourne, FL (US)

(21) Appl. No.: 18/801,887

(22) Filed: Aug. 13, 2024

(51) Int. Cl. G01R 29/08

(52) U.S. Cl. CPC G01R 29/0885

(57) ABSTRACT

A sensor receiver may include a Rydberg cell configured to be exposed to a radio frequency (RF) signal and a probe laser source may be configured to generate a sweeping probe laser beam within the Rydberg cell. An optical detector may be downstream from the Rydberg cell.

### FIELD OF THE INVENTION

The present invention relates to sensor receivers, and, more particularly, to a sensor receiver having a Rydberg cell and sensing atoms contained therein.

### BACKGROUND OF THE INVENTION

Radio frequency (RF) signals are generated and received in communications and sensing applications across a wide range of commercial markets and government divisions. Emerging RF applications are pushing technical requirements to higher frequency ranges with new waveforms that may be difficult to detect and that may need RF receivers or sensors having increased sensitivity. As conventional RF channels become more heavily crowded, there is a need to use alternative RF bands spanning from tens of KHz to 300 MHz and beyond. While some RF receivers and sensors span multiple RF bands, most are band-limited and can cover only a few tens of GHz, with a typical upper limit of about 40 GHz, e.g., the Ka band. Also, some state-of-the-art RF receivers and sensors are not compatible with new waveforms used in emerging distributed sensing networks and new RF applications that are sensitivity limited, or not served with existing narrow band antenna-based RF receivers and sensors.

Conventional RF devices that incorporate RF antennas may have a high technology readiness level (TRL) and are used in almost every modern RF sensing or communications system. There are limitations with RF antennas, however, because they may be Size, Weight and Power (SWaP) limited. The antenna is also on the order of the RF wavelength of radiation, and the RF coverage is over a relatively narrow frequency band, such as 1-10 GHz or 20-40 GHz. Many conventional RF devices employ antenna designs that are not compatible with emerging waveforms and may lack sensitivity, making them difficult to cover wide bandwidths with high sensitivity.

To address these limitations, Rydberg atom-based RF sensors have been developed, which convert the response of an atomic vapor to incoming RF radiation into measurable changes in an optical probe. These RF sensors provide a new model for RF sensing with increased sensitivity. For example, conventional antennas may provide at most about −130 to −160 dB of sensitivity, but with a Rydberg system, it can be up to about −200 dB with a broader range coverage in a single receiver from KHz to THz.

In a Rydberg atom-based RF sensor, the measurement is based upon the attenuation of a probe laser due to absorption in a small room temperature vapor cell filled with alkali atoms, such as rubidium (Rb) or cesium (Cs). In a two photon/laser Rydberg sensing system, atoms are simultaneously excited into a “Rydberg” state with both a coupling laser and probe laser. These Rydberg states are very responsive to local electric fields and the response of the atom to an external electric field, such as an RF signal, alters the measured attenuation of the probe laser, which may be detected by a probe laser photodetector. The magnitude of the electric field component of the incoming RF radiation and its center frequency detuning from atomic resonance may be determined by measuring the magnitude and asymmetry of spectral splitting of the electromagnetically induced transparency (EIT), which is called Autler Townes (AT) splitting.

Rydberg atom-based RF sensors have emerged as a viable option for surpassing the sensitivity limits of traditional dipole antenna-based receivers, while also reducing the SWaP, and enabling broad frequency coverage. However, current Rydberg sensors may not have realized their theoretical sensitivity limits. The best experimental demonstrations currently provide greater than 35 dB lower sensitivity than theoretical predictions. Accordingly, the best demonstrations may only be on par with traditional RF dipole antenna sensitivities. Some proposals have enhanced bandwidth in a Rydberg RF sensor receiver using a spatiotemporal multiplexing (STM) sensor receiver for high data rate sampling rates. However, there may be limitations in scalability due to SWaP considerations. In that proposed Rydberg STM sensor receiver, bulk optics use a fixed probe laser, and beam splitters and temporal delay lines may sample fresh Rydberg cell atoms in each measurement time.

### SUMMARY OF THE INVENTION

A sensor receiver may comprise a Rydberg cell configured to be exposed to a radio frequency (RF) signal. A probe laser source may be configured to generate a sweeping probe laser beam within the Rydberg cell. An optical detector may be downstream from the Rydberg cell. A controller may be associated with the probe laser source to control sweeping of the probe laser beam. The probe laser source may comprise an optical phased array, for example. The optical phased array may comprise a probe laser, and an array of optical phase modulators downstream from the probe laser.

The probe laser source may comprise a probe laser, and an Acousto-Optic Deflector (AOD) downstream from the probe laser. A coupling laser source may be configured to generate a coupling laser beam within the Rydberg cell. The coupling laser source may comprise a coupling laser, and a coupling sweep module downstream therefrom and synchronized with the sweeping probe laser beam.

Another aspect is directed to a method for receiving a radio frequency (RF) signal that may comprise exposing a Rydberg cell to the RF signal and operating a probe laser source to generate a sweeping probe laser beam within the Rydberg cell.

### BRIEF DESCRIPTION OF THE DRAWINGS

1Other objects, features and advantages of the present invention will become apparent from the detailed description of the invention which follows, when considered in light of the accompanying drawings in which:

FIG. 1 is a schematic diagram of a known Rydberg sensor receiver.

FIG. 2 is a schematic diagram of a Rydberg sensor receiver that generates a sweeping laser beam within a Rydberg cell using an optical phased array according to the invention.

FIG. 3 is a schematic diagram of the sensor receiver showing an array of optical phase modulators to sweep the probe laser beam within the Rydberg cell.

FIG. 4 is a schematic diagram of the sensor receiver showing an acousto-optic deflector to sweep the probe laser beam within the Rydberg cell.

FIG. 5 is a schematic diagram of the sensor receiver showing synchronized probe laser and coupler laser sweep modules to sweep both laser beams within the Rydberg cell.

FIG. 6 is a diagram showing nine-unique laser beam positions within the Rydberg cell that are selected from a 5×5 laser beam array with phase modulators.

FIG. 7 is an image showing a 5×5 array of 780 and 480 nanometer laser beams arranged between the array elements of FIG. 6.

FIG. 8 is a diagram of an example phase profile applied to each laser beam in the array of FIG. 7 that generates far field interference.

FIG. 9 is an image of the end beam profile from the array and phase profile shown in FIGS. 7 and 8.

FIG. 10 is a set of images showing the beginning and end laser beam profiles when the phase profile shown in FIG. 8 is used for steering at 20 MHz the probe laser beam to a first location.

FIG. 11 is a set of images similar to that shown in FIG. 10, but showing a third steered location for the probe laser beam.

FIG. 12 is another set of images showing a sixth steered location for the probe laser beam.

FIG. 13 is another set of images showing a ninth steered location for the probe laser beam.

FIG. 14 is a graph showing 0 Mhz detuning of the probe laser due to the instantaneous frequency being the rate of change of the phase profile when the probe laser beam is shifted to new spatial locations every 20 MHz as shown in FIGS. 10-14.

FIG. 15 is a graph showing 20 MHz detuning of the probe laser.

FIG. 16 is a flowchart showing the method of receiving the RF signal using the sensor receiver of FIG. 2-5.

FIG. 17 is a schematic diagram of a sensor receiver that uses an actuator to move the sensing atoms with respect to the probe laser beam according to the invention.

FIG. 18 is another schematic diagram of the sensor receiver showing an ultrasonic transducer as the actuator that moves the sensing atoms with respect to the probe laser beam.

FIG. 19 is a flowchart showing a method for receiving an RF signal using the sensor receiver shown in FIGS. 17 and 18.

### DETAILED DESCRIPTION

The present description is made with reference to the accompanying drawings, in which exemplary embodiments are shown. However, many different embodiments may be used, and thus, the description should not be construed as limited to the particular embodiments set forth herein. Rather, these embodiments are provided so that this disclosure will be thorough and complete. Like numbers refer to like elements throughout, and prime notation is used to indicate similar elements in different embodiments.

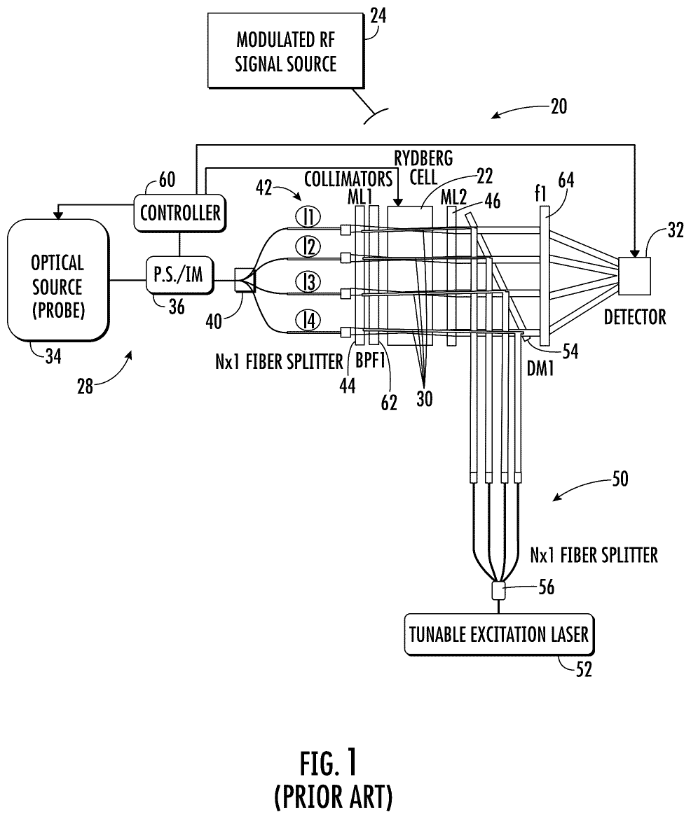

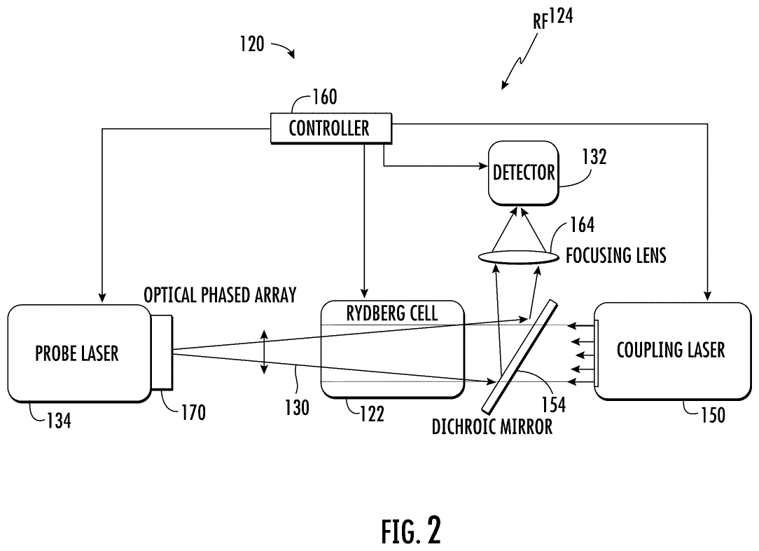

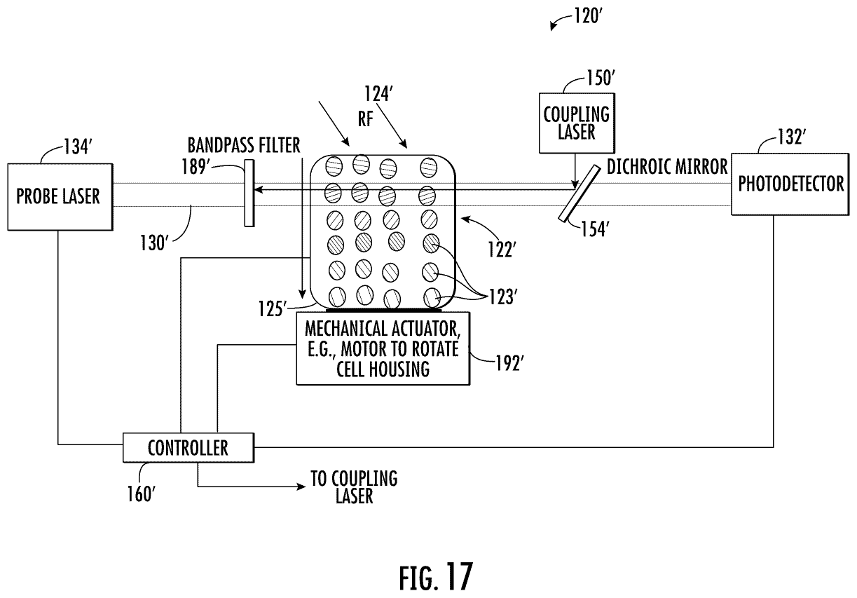

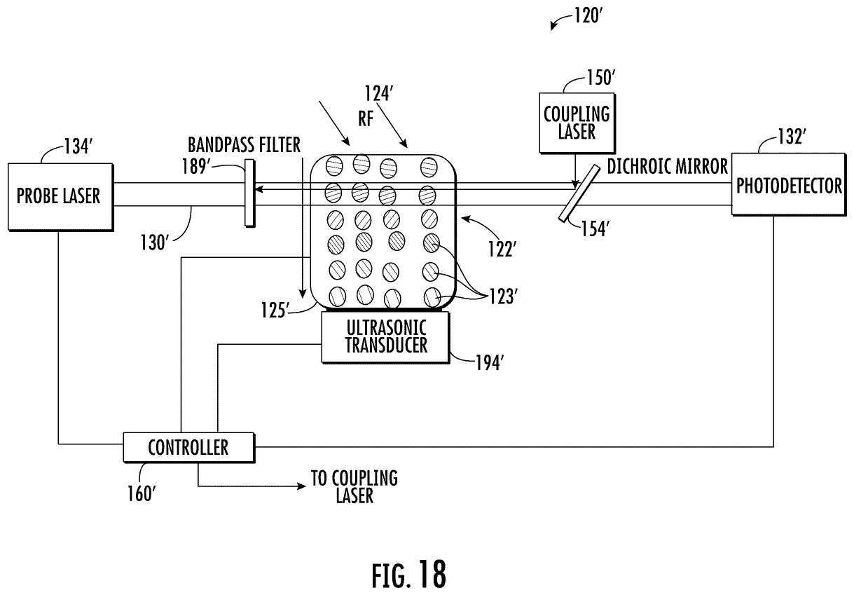

There now follows a description of a known Rydberg sensor receiver that operates as a spatiotemporal multiplexing (STM) Rydberg sensor receiver 20 for high data sampling rate as explained relative to FIG. 1, followed by the approach that increases the number of atoms participating in the measurement, such as by sweeping the probe laser beam within the Rydberg cell as shown in the sensor receiver 120 of FIGS. 2-5, or by moving the sensing atoms contained within the Rydberg cell with respect to the probe laser beam as shown in the sensor receiver 120′ of FIGS. 17 and 18. The approach of moving the sensing atoms contained in the Rydberg cell as described with reference to FIGS. 17 and 18 may be used to boost performance of sweeping the probe laser beam within the Rydberg cell, such that both may be used together.

Referring to FIG. 1, a known spatiotemporal multiplexing (STM) Rydberg sensor, also referred to as a Rydberg sensor receiver, is illustrated generally at 20 and includes a Rydberg cell 22 that is configured to be exposed to a radio frequency (RF) signal generated from a modulated RF signal source 24. This RF signal source 24 may include a non-modulated RF local oscillator. A laser probe source indicated generally at 28 is configured to generate a plurality of spaced apart pulsed probe beams within the Rydberg cell 22 and generally shown at 30, with the pulsed probe beams being offset in time from one another. It should be understood that one or more Rydberg cells may be used with the probe beams in multiple Rydberg cells. A detector 32 is positioned downstream from the Rydberg cell 22. In the illustrated example, the detector 32 is formed from a photodetector cell. The probe source 28 is configured to generate the plurality of spaced apart pulsed probe beams 30 in an example without scanning and may be formed as an optical source 34 with a pulse shaper 36 that is downstream from the optical source. The Rydberg sensor receiver 20 may work with and without scanning the probe beam. The pulse shaper 36 may be an intensity modulator.

In the illustrated example, the probe source 28 includes a beam splitter 40, such as a N×1 fiber splitter, downstream from the pulse shaper 36 and a respective optical delay element 42 in a path of each beam downstream from the beam splitter. Each optical delay element 42 may be formed as a respective different length of optical fiber shown by the loops indicated as L1, L2, L3 and L4. A first microlens 44 is positioned adjacent a first side of the Rydberg cell 22 and a second microlens 46 is positioned adjacent a second side of the Rydberg cell as illustrated by the designations ML1 and ML2.

An excitation source 50 as a coupling laser is coupled to the Rydberg cell 22 and formed as a tunable excitation laser 52 and at least one mirror 54, such as a dichroic mirror downstream therefrom to input the output of the excitation laser and excite the rubidium or cesium used within the Rydberg cell 22. For a 4-beam version, as shown in FIG. 1, the N×1 fiber splitter 56 is a 4×1 splitter and may split the output into four beams from the excitation laser 50 corresponding to the illustrated four probe beams 30. A controller 60 is coupled to the Rydberg cell 22, the optical source 34 as the laser probe of the probe source 28, and detector 32. The delay mechanism may not only delay tunability as noted above, but also direct modulation temporal gating of one or more excitation lasers 52.

As illustrated, a bandpass filter (BPF1) 62 may be included to block the excitation laser 52 and pass the spaced apart probe beams 30. This component may be a wavelength division multiplexer or a dichroic mirror. A plano convex lens (f1) 64 may focus the probe beams 30 to the detector 32. The first microlens 44 and bandpass filter 62 may be formed as a collimator device, e.g., a Thorlabs Part No. 50-780, and have a collimator output with about a 0.5 mm spot size beam at 780 nanometers as generated from the optical source 34 as a laser.

The Rydberg cell 22 is a rubidium Rydberg cell, such as Thorlabs part no. GC19075-RB. Other vapors of specific atomic elements may include Cesium (Cs), Potassium (K), Sodium (Na), and possibly Iodine (I). The Rydberg sensor receiver 20 as illustrated will temporally and spectrally shape the signature of the pulsed probe beams 30, and thus, allows an increase in the sampling rate as proportional to the number of beams “N.” Increasing the sampling rate is also dependent on the probe repetition rate. Separating the probe source 28 as a probe laser beam into N distinct pulses, each of which interrogates a distinct volume of the Rydberg cell 22, will increase the sampling of an incoming RF field in proportion to the number of beams “N.” In addition to increasing the sampling rate, the bandwidth of the probe pulses may also help reduce the latency usually incurred by scanning the probe beam across the EIT spectrum. This may reduce the latency from about 1 to 2 orders of magnitude. The temporal pulse width of the probe determines its spectral bandwidth through a Fourier transform.

It is possible to increase the probe bandwidth generated from the optical source 34 from about 100 KHz to about 200 MHz by choosing an appropriate pulse width. The incoming RF field may be mapped onto a spectroscopic fingerprint without scanning. The Rydberg sensor receiver 20 captures a response directly correlated to the integrated line absorption spectrum, i.e., the equivalent width for the case of the spectral character of the source propagating through the atomic vapor at/near the frequency of an atomic absorption line modified by the pressure of EIT. Further details of the Rydberg sensor 20 described with respect to FIG. 1 are explained in U.S. Pat. No. 11,598,798 to Bucklew et al., assigned to Eagle Technology, LLC, the disclosure which is hereby incorporated by reference in its entirety.

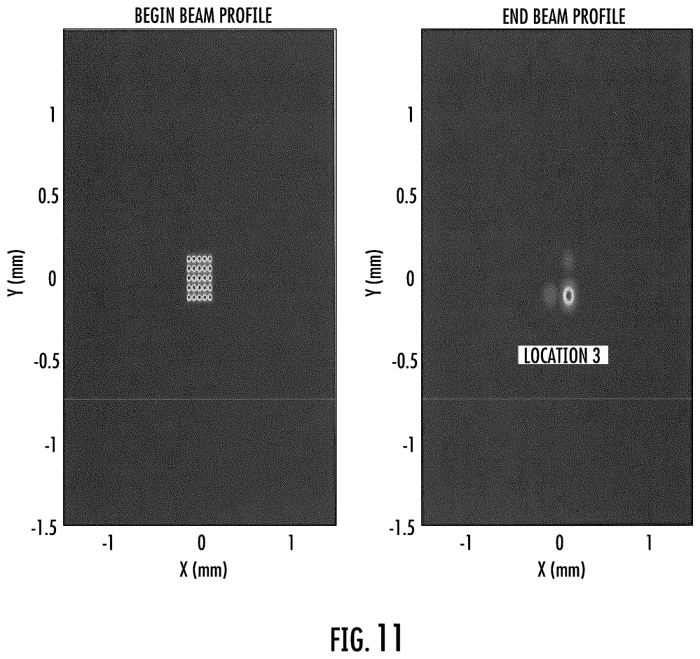

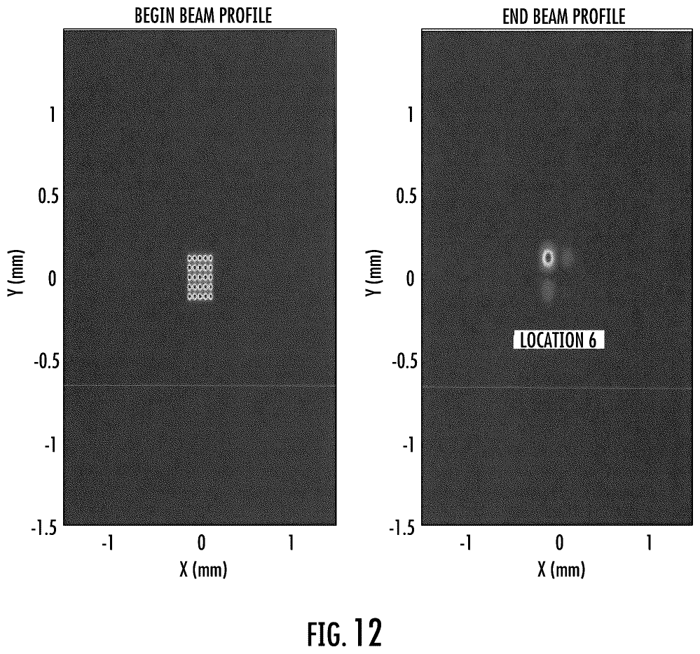

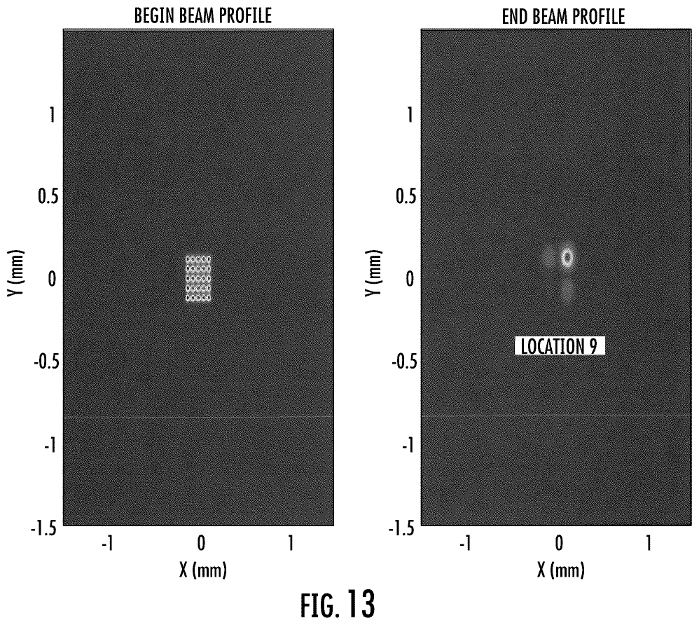

As will be explained with reference to the embodiments shown in FIGS. 2-19, it is possible to bring fresh Rydberg cell sensing atoms with respect to the probe laser beam without using multiple probe laser beams as in the incorporated by reference '798 patent. This can be accomplished by generating and sweeping the probe laser beam within the Rydberg cell or moving the sensing atoms within the Rydberg cell with respect to the probe laser beam. The approach of moving the sensing atoms in the Rydberg cell may be used to boost performance of sweeping the probe laser beam within the Rydberg cell, such that both may be used together. Similar components and elements for the sensor receiver 120,120′, described relative to FIGS. 2-19, are given common reference numerals in the 100 series.

The first embodiment shown in FIGS. 2-16 is directed to the sensor receiver 120 having its probe laser source 134 configured to generate a sweeping probe laser beam 130 within the Rydberg cell 122. The second embodiment of FIGS. 17-19 shows in detail a configuration of the sensor receiver 120′ where an actuator 190′ is configured to move the sensing atoms 123′ within the Rydberg cell 122′ with respect to the probe laser beam 130′. The sensor receiver 120′ may also have its probe laser beam 130′ swept since moving the atoms may be used to boost performance, and both may be used together.

As shown in FIG. 2, the sensor receiver 120 includes a Rydberg cell 122 that is configured to be exposed to a radio frequency (RF) signal 124, such as a modulated communications RF signal. A probe laser source 134 is configured to generate a sweeping probe laser beam 130 within the Rydberg cell 122. In this example of FIG. 2, the probe laser source 134 includes an optical phased array 170 that operates to generate with the probe laser source the sweeping probe laser beam 130 within the Rydberg cell 122.

The optical phased array 170 may be formed as a photonic integrated circuit with a beam scanner formed as a polymer waveguide, such as a tunable laser and optical phased array integrated on single or multiple chips. For example, the photonic integrated circuit as a chip may contain a polymer waveguide Bragg reflector, a power splitter, a phase modulator array, and beam concentrator as non-limiting examples. Fluorinated polymer materials may also be used. The probe laser 134 may be integrated in this example into the optical phased array 170, which allows the probe laser beam 130 to be swept quickly across the Rydberg cell 122.

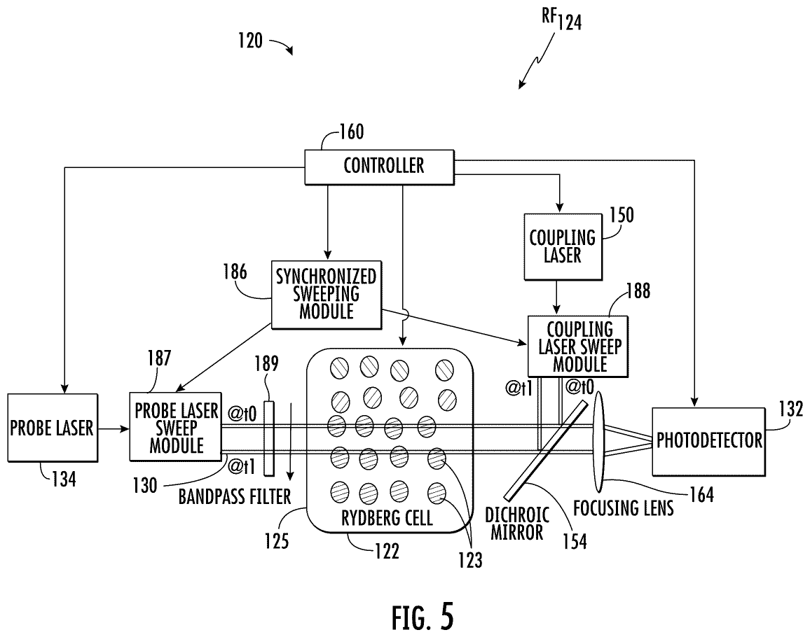

A coupling laser source 150 generates a coupling laser beam that may overfill the Rydberg cell 122 as illustrated diagrammatically with the multiple arrows, so that each spatial end beam position of the probe laser beam 130 within the Rydberg cell 122 pumps the sensing atoms 123 contained within the cell housing 125 of the Rydberg cell (FIG. 5), and pumps the sensing atoms into the Rydberg state, suitable for RF signal 124 measurement. The dichroic mirror 154, as in the example of FIG. 1, allows the coupling laser beam generated from the coupling laser source 150 to pass through and into the Rydberg cell 122 while also reflecting the probe laser beam 130 from the probe laser source 134 into a focusing lens 164 and into the detector 132, such as a photodetector. The controller 160 may operate with and be connected to the probe laser source 134, Rydberg cell 122, detector 132 and coupling laser source 150 as illustrated. Either a 2-laser or 3-laser excitation system may be used together.

Because the probe laser beam 130 is always interrogating fresh sensing atoms 123 contained within the cell housing 125 of the Rydberg cell 122, the bandwidth of this sensor receiver 120 is enhanced, and previous measurements do not degrade the signal-to-noise ratio of the RF signal 124 measurement. The focusing lens 164 may capture the probe laser beam 130 and focus it onto the detector 132 at a single spot.

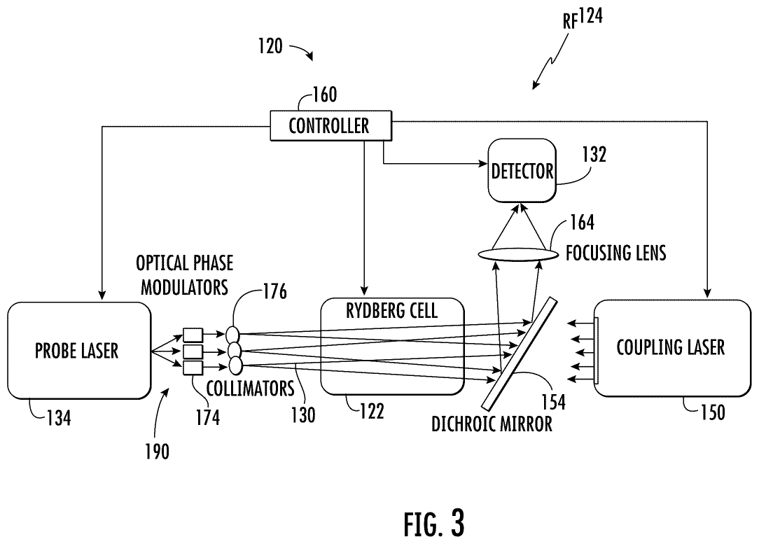

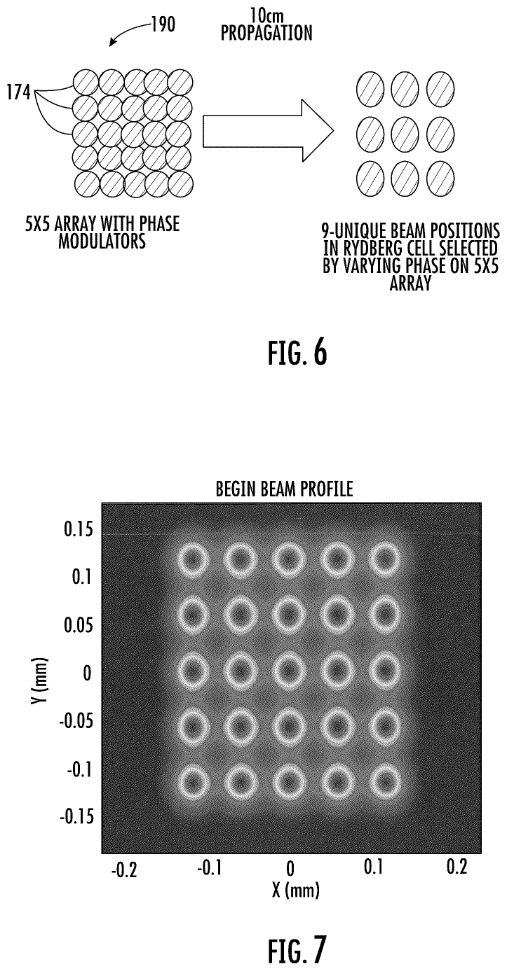

In the example of FIG. 3, optical phase modulators 172 and collimators 174, each formed from a microlens and bandpass filter, are employed with the probe laser source 134 to sweep the probe laser beam 130 within the Rydberg cell 122. The optical phase modulators 174 and respective collimators 176 may be part of an optical phased array 170 of the sensor receiver 120 of FIG. 2. Different types of optical phase modulators 174 may be used, such as electro-optic modulators based on pockels cells and liquid crystal modulators. It may be possible to exploit thermally induced refractive index changes or length changes of an optical fiber, or induce length changes in an optical fiber by stretching to impart phase changes. In an example, modulated light may propagate into waveguides and the phase modulators may have spatial control. Although an array 190 of optical phase modulators 174 is shown downstream from the probe laser 134 in FIG. 3, and illustrated as three optical phase modulators and three collimators 176, this limited number is shown for reference only, and a large plurality of optical phase modulators 174 may be formed in an array downstream from the probe laser, such as the 5×5 array with the phase modulators shown in FIG. 6.

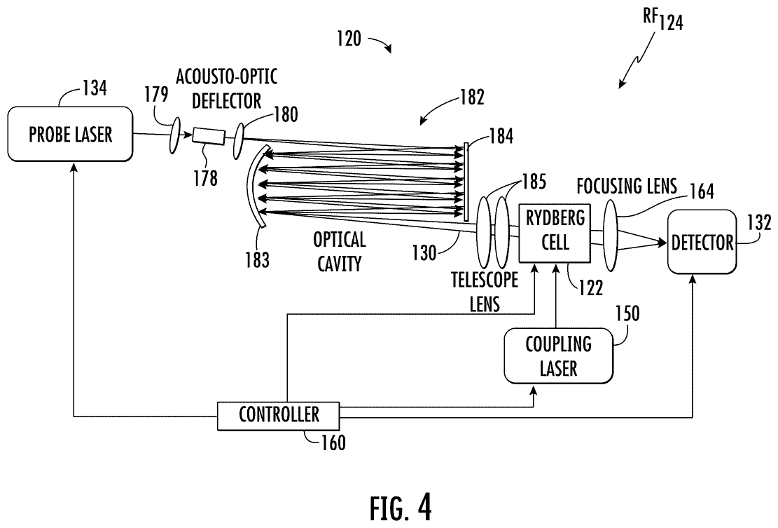

A different example of the sensor receiver 120 that incorporates an acousto-optic deflector (AOD) 178 downstream from the probe laser 134 is shown in FIG. 4. The probe laser beam 130 is generated through an input focusing lens 179 into the acousto-optic deflector 178 and out through an exit focusing lens 180 into an optical cavity 182 formed by optical mirrors, such as a concave mirror 183 and flat mirror 184 shown in FIG. 4. The optical cavity 182 may operate to amplify and deflect the probe laser beam 130 into a pair of telescope lenses 185, to be swept into the Rydberg cell 122, where it exits into a focusing lens 164 and detector 132. The coupling laser source 150 operates similar to the coupling laser source shown in the sensor receiver 120 of FIGS. 2 and 3.

Referring now to the sensor receiver 120 shown in FIG. 5, for reference purposes, the Rydberg cell 122 is shown to include its cell housing 125 and sensing atoms 123 contained therein. A synchronized sweeping module 186 operates with a probe laser sweep module 187 and coupling laser sweep module 188 so that both the probe laser beam 130 and coupling laser beam are spatially swept across the Rydberg cell 122. The coupling laser sweep module 188 is synchronized with the probe laser sweep module 187 via the synchronized sweeping module 186, which is controlled via the controller 160, so that the coupling laser beam and probe laser beam 130 are synchronized to each other. A bandpass filter 189 may be incorporated between the Rydberg cell 122 and the probe laser sweep module 187 and operate to allow a specific probe laser beam to sweep from time t0 to t1. As in the sensor receivers 120 shown in FIGS. 2 and 3, a dichroic mirror 154 and focusing lens 164 may be incorporated. The coupling laser sweep module 188 may include one or more lasers to form a multiple laser excitation system.

The probe sweep module 187 and its bandpass filter 189 may sweep the probe laser beam from time t0 through t1, and the coupling laser beam generated from the coupling laser source 150 is swept over the same time from t0 to t1. The number of locations in the Rydberg cell 122 that the coupling laser beam and probe laser beam 130 sweep is chosen so that the Rydberg cell sensing atoms 123 have time to “relax” and “recover” between successive measurements. Optical phased arrays 170 have been demonstrated to operate with 40+ MHz switching speeds. The sensor receiver 120 applies this sweeping technology at specific time scales within the Rydberg cell 122 to enable high data sampling rates in a low SWaP sensor receiver package.

Referring now to FIG. 6, the diagram shows generally at 190 a 5×5 array of optical phase modulators 174 that vary the phase of the probe laser beam 130 to output at the Rydberg cell 122 nine unique probe laser beam 130 positions as shown on the right-hand side of the diagram in FIG. 6. An example array 190 may be a photonic crystal surface-emitting laser (PCSEL) array with a 30 micrometer beam size that is spaced apart by 60 micrometers and spaced 10 centimeters in this example from the Rydberg cell 122 to allow a 10 centimeter laser propagation distance. An image of the 5×5 laser beam array 190 is shown in FIG. 7, which shows an array of 780 nanometer and 480 nanometer laser beams that are each arranged with the desired beam size and spacing in millimeters along the X and Y axis between the array elements. Referring again to FIG. 6, nine unique beam positions in the Rydberg cell 122 as shown in the right-hand side of the diagram may be selected by varying the phase on the optical phase modulators 174 in the 5×5 array 190 using a beam size of about 200 micrometers.

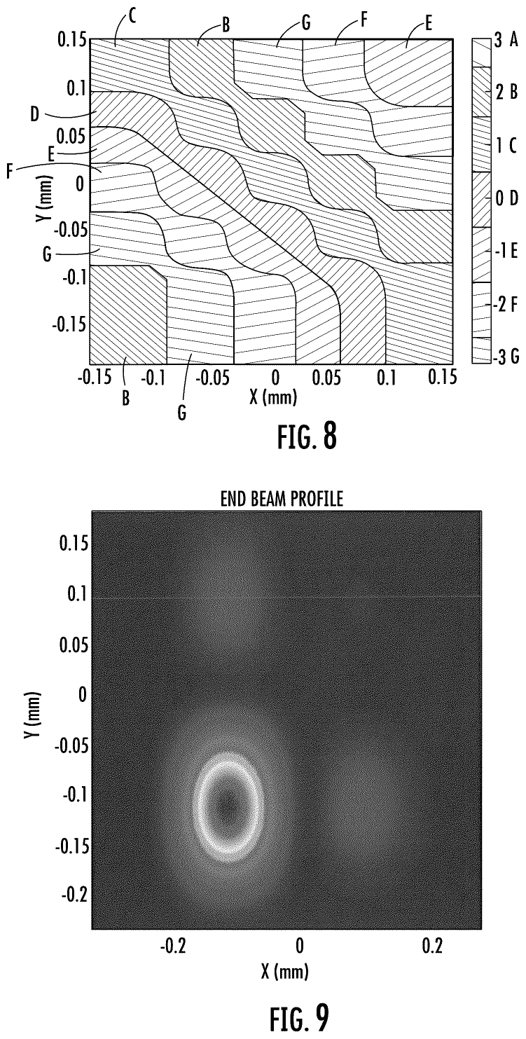

The phase profile as shown in FIG. 8 may be applied to the probe laser beam 130 in the array 190 to generate a far field interference pattern at a position in the Rydberg cell 122 where unique beam locations can be selected on demand. In FIG. 9, the end beam profile for the probe laser beam 130 at the Rydberg cell 122 is shown where the phase patterns may repeat at every upper state lifetime of the Rydberg sensing atoms 123, for example, 1 to 2 MHz, and cycle through various patterns at a speed determined by how many independent laser beams are accessible with the array 190 of optical phase modulators 174 forming the beam steering. For example, for a 10-accessible beam position array, and a 2 MHz repetition rate, phased profiles would change every 20 MHz.

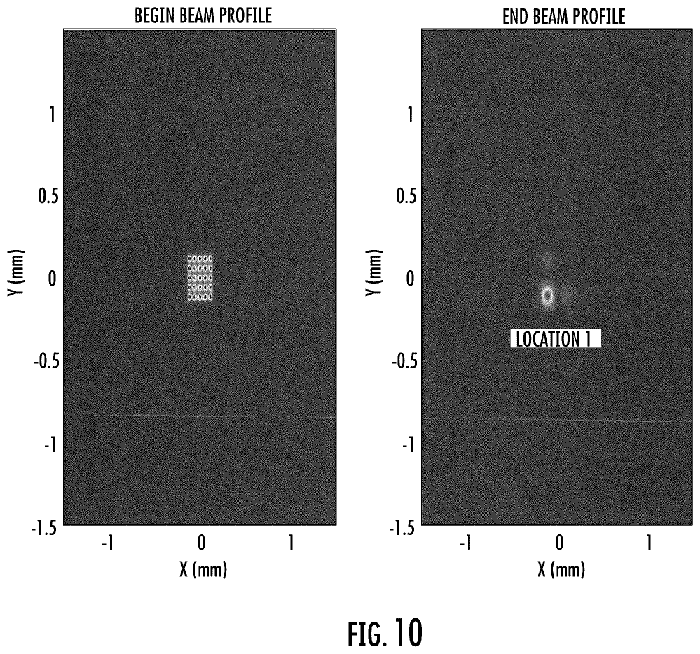

FIGS. 10-13 illustrate four respective sets of images with the beginning beam profile on the left-hand side image and the end beam profile on the right-hand side image. These figures show respective first, third, sixth, and ninth locations where the steering occurs at 20 MHz, i.e., changing the phase pattern every 20 MHz. This results in fresh Rydberg cell 122 sensing atoms 123 being introduced into each measurement.

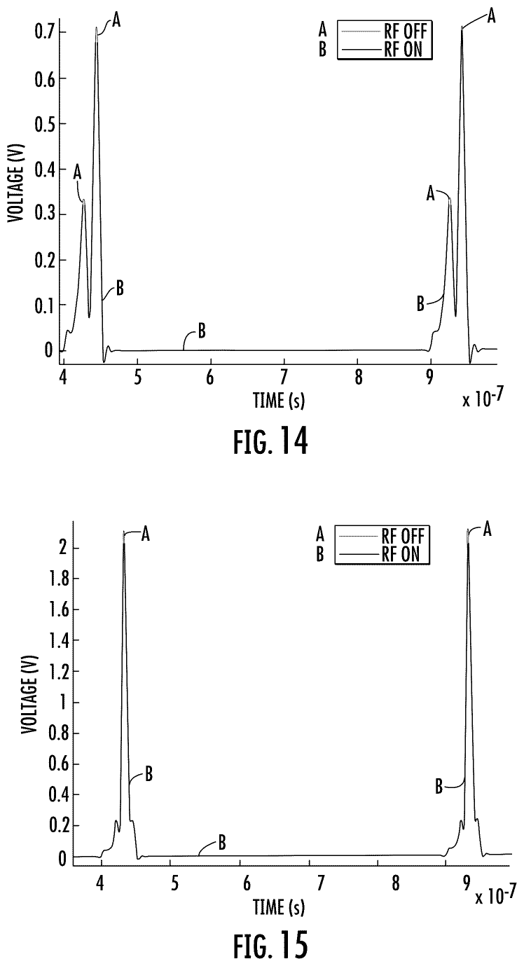

A simulated study of the sensor receiver 120 at a 20 MHz symbol rate is shown in the graphs of FIGS. 14 and 15. In FIG. 14, the graph shows a 0 MHz each detuning of the probe laser 134. As the phase shifting at the optical phase modulators 174 are applied at 20 MHz in this example, the sensor receiver 120 shifts the probe laser beam 130 to new spatial locations every 20 MHz. This applies a frequency shift on the probe laser 134 due to the instantaneous frequency being the rate of change of the phased profile, and translates to a probe laser detuning of a pulsed probe laser beam 130 at each moment in time.

This process may be simulated as shown in the graphs of FIGS. 14 and 15. As illustrated in those graphs, whether there is no detuning (FIG. 14), or 20 MHz detuning (FIG. 15), there is still an ability to discern between the radio frequency (RF) signal 124 on and off states, which is required for applications involving radio frequency communications, collections, and tracking. The array 190 of laser beams should all have the same frequency shift of about 20 MHz due to the repetitive, linear nature of the applied phase changes. However, certain patterns may not repeat immediately, and this may require the need to maintain detection of radio frequency signal 124 on and off states between 0 and 20 MHz probe laser detuning that is required as shown in the graphs of FIGS. 14 and 15.

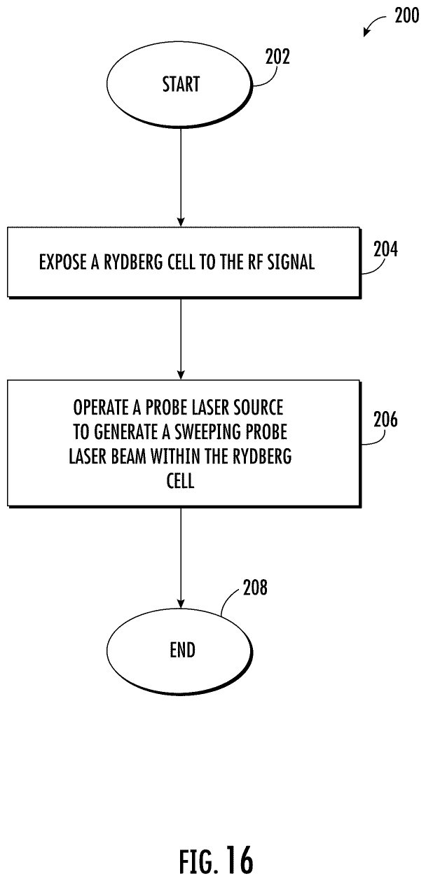

Referring now to FIG. 16, there is illustrated generally at 200 a flowchart showing an example method of receiving a radio frequency (RF) signal 124. The method starts (Block 202) and a Rydberg cell 122 is exposed to the RF signal 124 (Block 204). A probe laser source 134 is operated to generate a sweeping probe laser beam 130 within the Rydberg cell 122 (Block 206). The process ends (Block 208).

Referring now to FIG. 17, there is illustrated a sensor receiver 120′ where an actuator 192′ is configured to move the sensing atoms 123′ contained in the cell housing 125′ of the Rydberg cell 122′ with respect to the probe laser beam 130′ generated from the probe laser source 134′. This sensor receiver 120′ design of moving the atoms may be used to boost performance when the probe laser beam is swept, such that both sweeping of the probe laser beam and moving the atoms are used together. In this example, the actuator 192′ may be formed as a mechanical actuator to move the cell housing 125′, such as a motor to rotate the cell housing 125′ relative to the probe laser beam 130′. The sensor receiver 120′ includes the optical detector 132′ as an example photodetector downstream from the Rydberg cell 122′, and a bandpass filter 189′ that receives the probe laser beam 130′ into the Rydberg cell. A dichroic mirror 154′ cooperates with the coupling laser source 150′ and probe laser source 134′ so that the probe laser beam 130′ passes therethrough to the photodetector 132′. The probe laser source 134′, actuator 192′, coupling laser source 150′ and photodetector 132′ are connected to the controller 160′ as in the sensor receiver 120 examples of FIGS. 2-5.

The Rydberg cell 122′ when rotating may continuously sweep away sensing atoms 123′ involved in the measurement, and bring “fresh” sensing atoms into the probe laser beam 130′ to make a measurement, enabling a similarity with a spatiotemporal multiplexing configuration of the prior art example of FIG. 1 without requiring multiple probe laser beams. In the other example shown in FIG. 17, instead of a mechanical actuator 192′, the actuator may be formed as an ultrasonic transducer 194′ that operates as a high-speed megahertz transducer that enables the Rydberg cell 122′ sensing atoms 123′ to circulate and minimize the electron relaxation time to create “fresh” electrons. An example ultrasonic transducer 194′ may be a 3 MHz, 25 millimeter ultrasonic piezo-transducer, such as mounted on aluminum/stainless steel housing sold by Steminc as Part No. SMMSG25F3000.

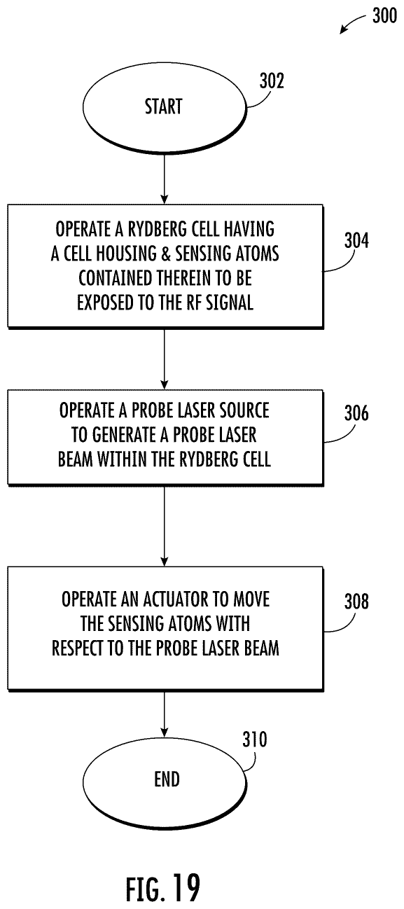

Referring now to FIG. 19, there is illustrated generally at 300 a flowchart showing an example for receiving a radio frequency (RF) signal 124′. The process starts (Block 302) and the method includes operating a Rydberg cell 122′ comprising a cell housing 125′ and sensing atoms 123′ contained therein to be exposed to the RF signal 124′ (Block 304). A probe laser source 134′ is operated to generate a probe laser beam within the Rydberg cell 122′ (Block 306). An actuator 192′ is operated to move the sensing atoms 123′ with respect to the probe laser beam (Block 308). The process ends (Block 310).

1This application is related to copending patent applications entitled, “SENSOR RECEIVER HAVING RYDBERG CELL SENSING ATOMS THAT MOVE WITH RESPECT TO PROBE LASER BEAM AND ASSOCIATED METHODS,” which is filed on the same date and by the same assignee and inventors, the disclosure which is hereby incorporated by reference.

Many modifications and other embodiments of the invention will come to the mind of one skilled in the art having the benefit of the teachings presented in the foregoing descriptions and the associated drawings. Therefore, it is understood that the invention is not to be limited to the specific embodiments disclosed, and that modifications and embodiments are intended to be included within the scope of the appended claims.

1. A sensor receiver comprising:
a Rydberg cell configured to be exposed to a radio frequency (RF) signal; and
a probe laser source configured to generate a sweeping probe laser beam within the Rydberg cell.

2. The sensor receiver of claim 1, comprising an optical detector downstream from the Rydberg cell.

3. The sensor receiver of claim 1, comprising a controller associated with the probe laser source to control sweeping of the probe laser beam.

4. The sensor receiver of claim 1, wherein the probe laser source comprises an optical phased array.

5. The sensor receiver of claim 4, wherein the optical phased array comprises a probe laser, and an array of optical phase modulators downstream from the probe laser.

6. The sensor receiver of claim 1, wherein the probe laser source comprises a probe laser, and an Acousto-Optic Deflector (AOD) downstream from the probe laser.

7. The sensor receiver of claim 1, comprising a coupling laser source configured to generate a coupling laser beam within the Rydberg cell.

8. The sensor receiver of claim 7, wherein the coupling laser source comprises a coupling laser, and a coupling sweep module downstream therefrom and synchronized with the sweeping probe laser beam.

9. A sensor receiver comprising:
a Rydberg cell configured to be exposed to a radio frequency (RF) signal;
a probe laser source configured to generate a sweeping probe laser beam within the Rydberg cell;
an optical detector downstream from the Rydberg cell; and
a controller coupled to the probe laser source and optical detector.

10. The sensor receiver of claim 9, wherein the probe laser source comprises an optical phased array.

11. The sensor receiver of claim 10, wherein the optical phased array comprises a probe laser, and an array of optical phase modulators downstream from the probe laser.

12. The sensor receiver of claim 9, wherein the probe laser source comprises a probe laser, and an Acousto-Optic Deflector (AOD) downstream from the probe laser.

13. The sensor receiver of claim 9, comprising a coupling laser source configured to generate a coupling laser beam within the Rydberg cell.

14. The sensor receiver of claim 13, wherein the coupling laser source comprises a coupling laser, and a coupling sweep module downstream therefrom and synchronized with the sweeping probe laser beam.

15. A method for receiving a radio frequency (RF) signal comprising:
exposing a Rydberg cell to the RF signal; and
operating a probe laser source to generate a sweeping probe laser beam within the Rydberg cell.

16. The method of claim 15, comprising operating an optical detector downstream from the Rydberg cell.

17. The method of claim 15, comprising operating a controller associated with the probe laser source to control sweeping of the probe laser beam.

18. The method of claim 15, wherein the probe laser source comprises an optical phased array.

19. The method of claim 18, wherein the optical phased array comprises a probe laser, and an array of optical phase modulators downstream from the probe laser.

20. The method of claim 15, wherein the probe laser source comprises a probe laser, and an Acousto-Optic Deflector (AOD) downstream from the probe laser.

21. The method of claim 15, comprising operating a coupling laser source to generate a coupling laser beam within the Rydberg cell.
